(19) United States
(12) Patent Application Publication
(10) Pub. No.: US 2025/0321605 A1
(43) Pub. Date: Oct. 16, 2025

(54) BANDGAP REFERENCE CIRCUIT

(71) Applicant: eMemory Technology Inc., Hsin-Chu (TW)

(72) Inventors: Hsin-Liang HO, Hsinchu County (TW); Chun-Fu Lin, Hsinchu County (TW)

(21) Appl. No.: 19/171,380

(22) Filed: Apr. 7, 2025

Related U.S. Application Data
(60) Provisional application No. 63/632,599, filed on Apr. 11, 2024.

(51) Int. Cl. G05F 3/26

(52) U.S. Cl. CPC G05F 3/267

(57) ABSTRACT

A bandgap reference circuit includes a bandgap voltage generator and a detector. The bandgap voltage generator includes an operation amplifier, an input circuit and a load circuit. The detector includes a control circuit and a response circuit. The two input terminals of the operation amplifier are respectively connected with a first node and a second node. An output terminal of the operation amplifier is connected with a bias node. The load circuit is connected with a third node. The input circuit is connected with the first node and the second node. The control circuit activates a sensing signal according to a bias voltage. When the sensing signal is activated, the bias node is connected with a power supply voltage through the response circuit. When the sensing signal is not activated, the bias node is disconnected from the power supply voltage through the response circuit.

This application claims the benefit of U.S. provisional application Ser. No. 63/632,599, filed Apr. 11, 2024, the subject matters of which is incorporated herein by reference.

### FIELD OF THE INVENTION

The present invention relates to a voltage generating circuit, and more particularly to a bandgap reference circuit.

### BACKGROUND OF THE INVENTION

As known, a bandgap reference circuit has a function of providing a stable bandgap voltage (VBG) that does not change with the process or temperature. In the field of a non-volatile memory, the bandgap voltage VBG can be used to generate more operation voltages.

For example, the non-volatile memory includes a charge pump (not shown). During a program action, the charge pump receives the bandgap voltage VBG and generates a program voltage. In response to the program voltage, the non-volatile memory can be subjected to the program action. There is a specified proportional relationship between the bandgap voltage VBG and the program voltage. Alternatively, during an erase action, the charge pump receives the bandgap voltage VBG and generates an erase voltage. In response to the erase voltage, the non-volatile memory can be subjected to an erase action. There is another specified proportional relationship between the bandgap voltage VBG and the erase voltage. Since the bandgap reference circuit can provide a stable bandgap voltage VBG, the charge pump can also generate the stable program voltage or the stable erase voltage.

### SUMMARY OF THE INVENTION

An embodiment of the present invention provides a bandgap reference circuit. The bandgap reference circuit includes a bandgap voltage generator and a detector. The bandgap voltage generator includes a mirroring circuit, an operation amplifier, an input circuit and a load circuit. A negative input terminal of the operation amplifier is connected with a first node of the mirroring circuit. A positive input terminal of the operation amplifier is connected with a second node of the mirroring circuit. An output terminal of the operation amplifier is connected with a bias node of the mirroring circuit. The load circuit is connected with a third node of the mirroring circuit. The input circuit is connected with the first node and the second node of the mirroring circuit. A voltage at the third node is a bandgap voltage. The detector includes a control circuit and a response circuit. The control circuit is connected with at least one of the bias node and the third node. The control circuit activates a sensing signal according to a bias voltage at the bias node or the bandgap voltage at the third node. The response circuit receives the sensing signal. When the sensing signal is activated, the first node is connected with a first power supply voltage through the response circuit, or the bias node is connected with a second power supply voltage through the response circuit, or the second node is connected with the second power supply voltage through the response circuit. When the sensing signal is not activated, the first node is disconnected from the first power supply voltage through the response circuit, or the bias node is disconnected from the second power supply voltage through the response circuit, or the second node is disconnected from the second power supply voltage through the response circuit. The first power supply voltage is greater than the second power supply voltage.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic circuit diagram illustrating a bandgap voltage generator according to an embodiment of the present invention;

FIG. 2A is a schematic circuit diagram illustrating a bandgap reference circuit according to a first embodiment of the present invention;

FIG. 2B is a schematic circuit diagram illustrating a first exemplary detector of the bandgap reference circuit according to the first embodiment of the present invention;

FIG. 2C is a schematic circuit diagram illustrating a second exemplary detector of the bandgap reference circuit according to the first embodiment of the present invention;

FIG. 3A is a schematic circuit diagram illustrating a bandgap reference circuit according to a second embodiment of the present invention;

FIG. 3B is a schematic circuit diagram illustrating a first exemplary detector of the bandgap reference circuit according to the second embodiment of the present invention;

FIG. 3C is a schematic circuit diagram illustrating another response circuit in the detector of the bandgap reference circuit according to the second embodiment of the present invention;

FIG. 3D is a schematic circuit diagram illustrating a third exemplary detector of the bandgap reference circuit according to the second embodiment of the present invention;

FIG. 3E is a schematic circuit diagram illustrating another response circuit in the detector of the bandgap reference circuit according to the second embodiment of the present invention;

FIG. 4A is a schematic circuit diagram illustrating a bandgap reference circuit according to a third embodiment of the present invention;

FIG. 4B is a schematic circuit diagram illustrating a first exemplary detector of the bandgap reference circuit according to the third embodiment of the present invention;

FIG. 4C is a schematic circuit diagram illustrating another response circuit in the detector of the bandgap reference circuit according to the third embodiment of the present invention;

FIG. 4D is a schematic circuit diagram illustrating a third exemplary detector of the bandgap reference circuit according to the third embodiment of the present invention;

FIG. 4E is a schematic circuit diagram illustrating a fifth exemplary detector of the bandgap reference circuit according to the third embodiment of the present invention;

FIG. 4F is a schematic circuit diagram illustrating a seventh exemplary detector of the bandgap reference circuit according to the third embodiment of the present invention;

FIG. 5 is a schematic circuit diagram illustrating an exemplary detector of a bandgap reference circuit according to a fourth embodiment of the present invention;

FIG. 6 is a schematic circuit diagram illustrating an exemplary detector of a bandgap reference circuit according to a fifth embodiment of the present invention;

FIG. 7 is a schematic circuit diagram illustrating a variant example of the bandgap voltage generator; and

FIGS. 8A, 8B and 8C are schematic circuit diagrams illustrating other three examples of the bandgap reference circuit of the present invention.

### DETAILED DESCRIPTION OF PREFERRED EMBODIMENTS

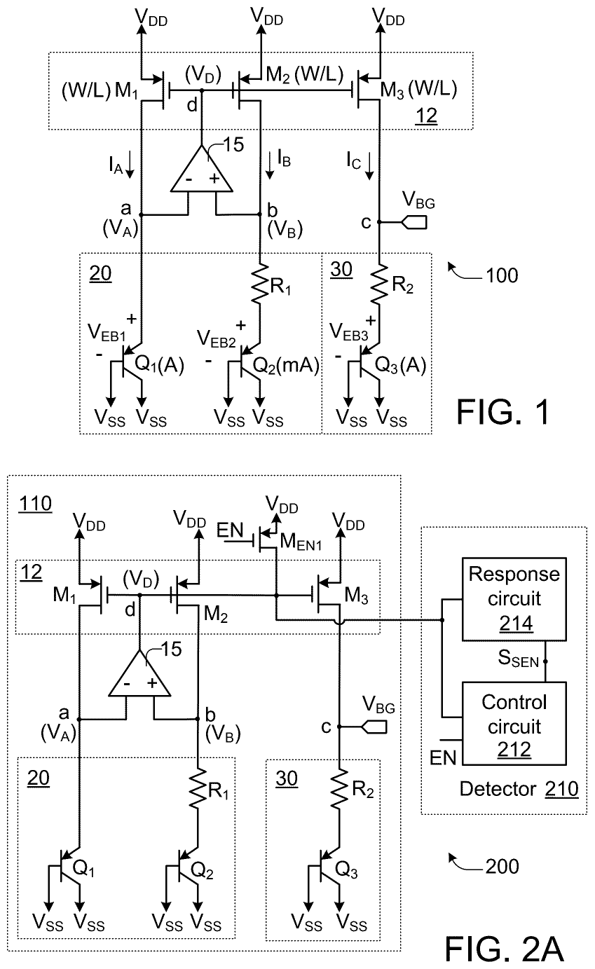

FIG. 1 is a schematic circuit diagram illustrating a bandgap voltage generator according to an embodiment of the present invention. As shown in FIG. 1, the bandgap voltage generator 100 includes a mirroring circuit 12, an operation amplifier 15, an input circuit 20 and a load circuit 30.

The mirroring circuit 12 includes three p-type FET transistors M₁, M₂ and M₃. The gate terminals of the transistors M₁, M₂ and M₃ are connected with each other and connected with a bias node d. The source terminals of the transistors M₁, M₂ and M₃ receive a power supply voltage V_{DD}. The drain terminals of the transistors M₁, M₂ and M₃ are respectively connected with the nodes a, b and c. The drain terminal of the transistor M₁ outputs a current I_{A}. The drain terminal of the transistor M₂ outputs a current I_{B}. The drain terminal of the transistor M₃ outputs a current I_{C}.

An output terminal of the operation amplifier 15 is connected with the bias node d of the mirroring circuit 12. A negative input terminal of the operation amplifier 15 is connected with the node a. A positive input terminal of the operation amplifier 15 is connected with the node b.

The input circuit 20 is connected with the node a and the node b. The input circuit 20 includes two PNP bipolar junction transistors (PNP BJT transistors) Q₁ and Q₂. The base and the collector of the transistor Q₁ receive a power supply voltage Vss. Consequently, the transistor Q₁ has a diode-connected structure. The base and the collector of the transistor Q₂ receive the power supply voltage Vss. Consequently, the transistor Q₂ has a diode-connected structure. The magnitude of the power supply voltage V_{DD} is higher than the magnitude of the power supply voltage Vss. For example, the power supply voltage Vss is a ground voltage. The emitter of the transistor Q₁ is connected with the node a. A first resistor R₁ is connected between the emitter of the transistor Q₂ and the node b.

The load circuit 30 is connected with the node c. The load circuit 30 includes a PNP bipolar junction transistor Q₃. The base and collector of the transistor Q₃ receive the power supply voltage Vss. A second resistor R₂ is connected between the emitter of the transistor Q₃ and the node c. The voltage at the node c is the bandgap voltage VBG.

In the bandgap voltage generator 100 of FIG. 1, the transistor M₁, the transistor M₂ and the transistor M₃ have the same aspect ratio (W/L). The area of the transistor Q₂ is m times the area of the transistor Q₁. The area of the transistor Q₃ is the same as that of the transistor Q₁. It is noted that the aspect ratios of the transistors M₁, M₂ and M₃ may be varied according to the practical requirements. Similarly, the relationships between the areas of the three transistors Q₁, Q₂ and Q₃ may be varied according to the practical requirements.

Since the transistors M₁, M₂ and M₃ have the same aspect ratio, the magnitude of the output current I_{A} from the drain terminal of the transistor M₁, the magnitude of the output current I_{B} from the drain terminal of the transistor M₂ and the magnitude of the output current I_{C} from the drain terminal of the transistor M₃ are equal. That is, the relationships between the output currents I_{A}, I_{B} and I_{C} may be expressed by the following formula (1): I_{A}=I_{B}=I_{C}.

In case that the operation amplifier 15 has an infinite open loop gain, the negative input voltage VA and the positive input voltage VB of the operation amplifier 15 are equal. Consequently, the following formula (2) is obtained: R₁×I_{B}+V_{EB2}=V_{EB1}, wherein V_{EB1} is the emitter-base voltage of the transistor Q₁, and V_{EB2} is the emitter-base voltage of the transistor Q₂.

As mentioned above, the transistors Q₁ and Q₂ have the diode-connected structure, and the area of the transistor Q₂ is m times the area of the transistor Q₁. Consequently, the relationships between the I_{A}, I_{B}, V_{EB1} and V_{EB2} may be expressed by the following formulae:

$$\begin{matrix}{I}_{A} = {I}_{S} \cdot {e}^{\frac{{V}_{{EB}_{1}}}{{V}_{T}}} \\ {I}_{B} = m \cdot {I}_{S} \cdot {e}^{\frac{{V}_{{EB}_{2}}}{{V}_{T}}}\end{matrix}$$

Consequently, the following formulae (3) and (4) are obtained.

$${V}_{BE 1} = {V}_{T} \times ln ( {I}_{A} / {I}_{S} ) \qquad ( 3 )$$

$${V}_{BE 2} = {V}_{T} \times ln ( {I}_{B} / m \times {I}_{S} ) \qquad ( 4 )$$

In the above formulae, I_{S} is the saturation current of the transistor Q₂, and V_{T} is a thermal voltage.

According to the formulae (1), (2), (3) and (4), the following formula (5) is obtained: V_{BG}=(R₂/R₁)×V_{T}×In(m)+V_{EB3}, wherein V_{EB3} is the emitter-base voltage of the transistor Q3.

In the formula (5), the bandgap voltage V_{BG} can be regarded as a base-emitter voltage V_{BE3} plus a thermal voltage V_{T} multiplied by a temperature-independent scalar C₁. That is, V_{BG}=V_{BE3}+C₁×V_{T}, wherein C₁=(R₂/R₁)×In(m).

Generally, the base-emitter voltage V_{BE} has a negative temperature coefficient, and the thermal voltage V_{T} has the positive temperature coefficient. Consequently, after the coefficient C₁ is multiplied by the thermal voltage V_{T} and added to the base-emitter voltage V_{BE3}, a voltage value with a zero temperature coefficient can be obtained. In other words, the bandgap voltage VBG is almost a constant value at any temperature. Consequently, the bandgap voltage VBG nearly does not change with the temperature.

As mentioned above, when the bandgap voltage generator 100 is operated normally, the bandgap voltage generator 100 generates the bandgap voltage VBG that does not change with temperature. However, in case that the power supply voltage V_{DD} or the power supply voltage Vss is subjected to the disturbance and the generated power noise or ground noise is large, the bandgap voltage generator 100 possibly fails and is unable to generate the normal bandgap voltage VBG.

For example, when the non-volatile memory undergoes the program action or the erase action, the current in the non-volatile memory is very large. Due to the large current, the power supply voltage V_{DD} or the power supply voltage Vss is subjected to the disturbance. If the power noise or ground noise is large, the bandgap voltage generator 100 possibly fails. Once the bandgap voltage generator 100 fails, the non-volatile memory will not be able to generate the normal program voltage and the normal erase voltage to perform the program action and the erase action.

In case that power noise or ground noise is large, the voltage VB at the node b in the bandgap voltage generator 100 will rise and the voltage VA at the node a in the bandgap voltage generator 100 will drop. As a result, the voltage at the output terminal (i.e., the bias node d) of the operation amplifier 15 rises and the bandgap voltage VBG drops, causing the bandgap voltage generator 100 to fail. In order to avoid failure of the bandgap voltage generator 100 during operation, the present invention provides a bandgap reference circuit. The bandgap reference circuit is equipped with a detector. The detector can detect the node voltage change of the bandgap voltage generator 100. According to the node voltage change of the bandgap voltage generator 100, the detector judges whether the bandgap voltage generator 100 is about to fail and forces the bandgap voltage generator 100 to restore the normal operation.

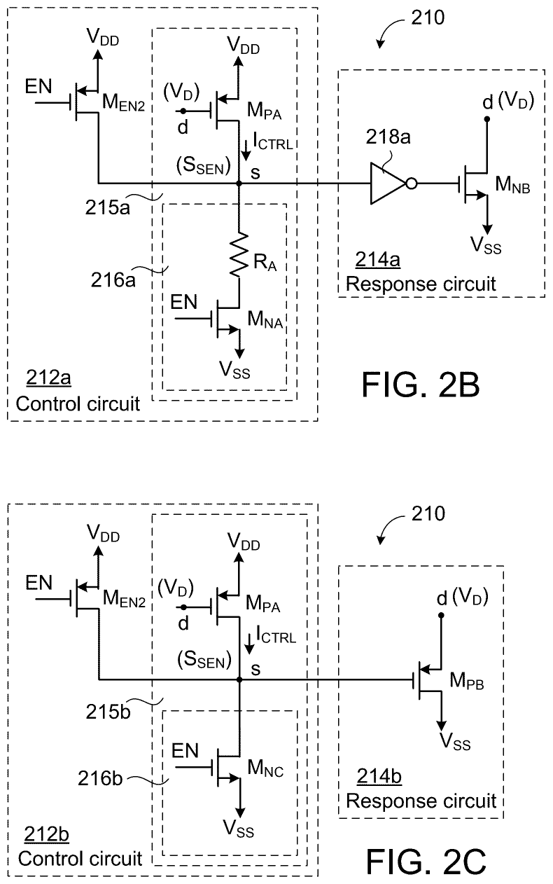

FIG. 2A is a schematic circuit diagram illustrating a bandgap reference circuit according to a first embodiment of the present invention. As shown in FIG. 2A, the bandgap reference circuit 200 includes a bandgap voltage generator 110 and a detector 210.

In comparison with the bandgap voltage generator 100 of FIG. 1, the bandgap voltage generator 110 of this embodiment further includes a P-type FET transistor M_{EN1}. For succinctness, only the connecting relationship between the P-type FET transistor M_{EN1} and the associated components will be described as follows. The source terminal of the transistor M_{EN1} receives the power supply voltage V_{DD}. The drain terminal of the transistor M_{EN1} is connected with the bias node d. The gate terminal of the transistor M_{EN1} receives an enable signal EN. Of course, the bandgap voltage generator 100 of FIG. 1 can also be used in the bandgap reference circuit 200 of the present invention.

When the enable signal EN is in a low logic level state, it means that the enable signal EN is not activated. When the enable signal EN is not activated, the transistor M_{EN1} is turned on, and a bias voltage VD at the bias node d is pulled up to the power supply voltage V_{DD}. Consequently, the transistors M₁, M₂ and M₃ are turned off. That is, the bandgap voltage generator 110 is disabled. Whereas, when the enable signal EN is in a high logic level state, it means that the enable signal EN is activated. When the enable signal EN is activated, the transistor M_{EN1} is turned off, and the transistors M₁, M₂ and M₃ are controlled in response to the bias voltage VD from the operational amplifier 15. Consequently, the bandgap voltage generator 110 is operated normally, and the bandgap voltage VBG is generated.

The detector 210 includes a control circuit 212 and a response circuit 214. When the enable signal EN is not activated, the detector 210 is disabled. When the enable signal EN is activated, the detector 210 is enabled.

The control circuit 212 receives the enable signal EN. The control circuit 212 is connected with the bias node d of the bandgap voltage generator 110 to detect the change of the bias voltage VD at the bias node d and generate a sensing signal S_{SEN} to the response circuit 214. The response circuit 214 is connected with the bias node d of the bandgap voltage generator 110. In addition, the response circuit 214 appropriately adjusts the bias voltage V_{D} at the bias node d according to the sensing signal S_{SEN}.

For example, in case that the power noise or the ground noise is large, the bias voltage VD from the output terminal of the operation amplifier 15 (i.e., the bias node d) in the bandgap voltage generator 110 increases. According to the change of the bias voltage V_{D}, the control circuit 212 selectively activates the sensing signal S_{SEN}. Consequently, the response circuit 214 decreases the bias voltage V_{D} at the bias node d. Hereinafter, some examples of the detector 210 in the bandgap reference circuit 200 of the first embodiment will be described.

FIG. 2B is a schematic circuit diagram illustrating a first exemplary detector of the bandgap reference circuit according to the first embodiment of the present invention. The detector 210 includes a control circuit 212a and a response circuit 214a. The control circuit 212a includes a P-type FET transistor M_{EN2} and a current control path 215a. The current control path 215a includes a P-type FET transistor MPA and a pull-down circuit 216a. The pull-down circuit 216a includes an N-type FET transistor MNA and a resistor RA.

The source terminal of the transistor M_{EN2} receives the power supply voltage V_{DD}. The drain terminal of the transistor M_{EN2} is connected with a sensing node s. The gate terminal of the transistor M_{EN2} receives the enable signal EN. The voltage at the sensing node s is used as the sensing signal S_{SEN}.

In the current control path 215a, the source terminal of the transistor M_{PA} receives the power supply voltage V_{DD}, the drain terminal of the transistor M_{PA} is connected with the sensing node s, and the gate terminal of the transistor M_{PA} is connected with the bias node d in the bandgap voltage generator 110. In addition, the pull-down circuit 216a is connected between the sensing node s and the power supply voltage V_{SS}. The first terminal of the resistor R_{A} is connected with the sensing node s. The drain terminal of the transistor MNA is connected with the second terminal of the resistor R_{A}. The source terminal of the transistor M_{NA} receives the power supply voltage V_{SS}. The gate terminal of the transistor M_{NA} receives the enable signal EN.

The response circuit 214a includes an inverter 218a and an N-type FET transistor M_{NB}. The transistor M_{NB} can be regarded as a switch transistor. The input terminal of the inverter 218a is connected with the sensing node s. The drain terminal of the transistor M_{NB} is connected with the bias node d. The source terminal of the transistor M_{NB} receives the power supply voltage V_{SS}. The gate terminal of the transistor M_{NB} is connected with the output terminal of the inverter 218a.

Please refer to FIG. 2B. When the enable signal EN is not activated (i.e., in the low logic level state), the transistor M_{EN2} is turned on, and the transistor M_{NA} is turned off. Under this circumstance, the voltage level of the sensing signal S_{SEN} is the power supply voltage V_{DD}, and a control current I_{CTRL} on the current control path 215a is zero. The inverter 218a issues a low logic level to the gate terminal of the transistor M_{NB}. Consequently, the transistor M_{NB} is turned off. In other words, when the enable signal EN is not activated (i.e., in the low logic level state), the sensing signal S_{SEN} at the sensing node s cannot be changed, indicating that the detector 210 is disabled.

When the enable signal EN is activated (i.e., in the high logic level state), the bandgap voltage generator 110 is enabled. In the control circuit 212a, the transistor M_{EN2} is turned off, and the transistor M_{NA} is turned on. Meanwhile, the control current I_{CTRL} generated by the transistor M_{PA} can be controlled according to the bias voltage V_{D} at the bias node d. As the control current I_{CTRL} is changed, the voltage level of the sensing signal S_{SEN} is correspondingly changed.

When the bandgap voltage generator 110 is operated normally, the transistor M_{PA} is turned on. Consequently, the voltage level of the sensing signal S_{SEN} is greater than the voltage level of a transition point of the inverter 218a. It means that the sensing signal S_{SEN} is not activated. The voltage at the output terminal of the inverter 218a is in the low logic level state. Consequently, the transistor M_{NB} is turned off.

In case that the power noise or the ground noise is large, the voltage V_{D} from the output terminal of the operation amplifier 15 (i.e., the bias node d) in the bandgap voltage generator 110 increases. Consequently, the control current I_{CTRL} decreases. Correspondingly, the voltage level of the sensing signal S_{SEN} decreases. If the voltage level of the sensing signal S_{SEN} is less than the voltage level of the transition point of the inverter 218a, the sensing signal S_{SEN} is activated. The output terminal of the inverter 218a is changed to the high logic level state. In addition, the transistor M_{NB} is turned on. Under this circumstance, the bias node d is connected with the power supply voltage V_{SS} through the switch transistor M_{NB} of the response circuit 214a. Consequently, the response circuit 214a stops increasing the bias voltage V_{D} continuously and decreases the bias voltage V_{D}. The bandgap voltage generator 110 is restored to the normal operation.

When the bandgap voltage generator 110 is restored to the normal operation, the sensing signal S_{SEN} is inactivated. Consequently, the transistor M_{NB} is turned off, and the bias node d is disconnected from the power supply voltage V_{SS} through the switch transistor M_{NB} of the response circuit 214a.

FIG. 2C is a schematic circuit diagram illustrating a second exemplary detector of the bandgap reference circuit according to the first embodiment of the present invention. The detector 210 includes a control circuit 212b and a response circuit 214b. The control circuit 212b includes a P-type FET transistor M_{EN2} and a current control path 215b. The current control path 215b includes a P-type FET transistor M_{PA} and a pull-down circuit 216b. The pull-down circuit 216b includes an N-type FET transistor MNC.

In the current control path 215b, the source terminal of the transistor M_{PA} receives the power supply voltage V_{DD}, the drain terminal of the transistor M_{PA} is connected with the sensing node s, and the gate terminal of the transistor M_{PA} is connected with the bias node d in the bandgap voltage generator 110. In addition, the pull-down circuit 216b is connected between the sensing node s and the power supply voltage V_{SS}. The drain terminal of the transistor M_{NC} is connected with the sensing node s. The source terminal of the transistor M_{NC} receives the power supply voltage V_{SS}. The gate terminal of the transistor M_{NC} receives the enable signal EN. In an embodiment, the transistor M_{NC} is a weak N-type FET. The size of the transistor M_{NC} is smaller than that of the transistor M_{PA}. The internal resistance of the transistor M_{NC} is greater than that of the transistor M_{PA}.

The response circuit 214b includes a P-type FET transistor MPB. The transistor MPB can be regarded as a switch transistor. The source terminal of the transistor MPB is connected with the bias node d. The drain terminal of the transistor MPB receives the power supply voltage V_{SS}. The gate terminal of the transistor MPB is connected with the sensing node s.

Please refer to FIG. 2C. When the enable signal EN is not activated (i.e., in the low logic level state), the detector 210 is disabled. When the enable signal EN is activated (i.e., in the high logic level state), the transistor M_{EN2} is turned off, and the transistor M_{NC} is turned on. Meanwhile, the control current I_{CTRL} generated by the transistor M_{PA} can be controlled according to the bias voltage V_{D} at the bias node d. As the control current I_{CTRL} is changed, the voltage level of the sensing signal S_{SEN} is correspondingly changed.

When the bandgap voltage generator 110 is operated normally, the transistor M_{PA} is turned on. Consequently, the voltage difference between the voltage level of the sensing signal S_{SEN} and the voltage at the bias node d is greater than a threshold voltage of the transistor MPB. It means that the sensing signal S_{SEN} is not activated. Consequently, the transistor MPB is turned off.

In case that the power noise or the ground noise is large, the voltage V_{D} from the output terminal of the operation amplifier 15 (i.e., the bias node d) in the bandgap voltage generator 110 increases. Consequently, the control current I_{CTRL} decreases. Correspondingly, the voltage level of the sensing signal S_{SEN} decreases. If the voltage difference between the voltage level of the sensing signal S_{SEN} and the voltage at the bias node d is less than threshold voltage of the transistor MPB, the sensing signal S_{SEN} is activated. In addition, the transistor MPB is turned on. Under this circumstance, the bias node d is connected with the power supply voltage V_{SS} through the switch transistor MPB of the response circuit 214B. Consequently, the response circuit 214B stops increasing the bias voltage V_{D} continuously and decreases the bias voltage V_{D}. The bandgap voltage generator 110 is restored to the normal operation.

When the bandgap voltage generator 110 is restored to the normal operation, the sensing signal S_{SEN} is inactivated. Consequently, the transistor MPB is turned off, and the bias node d is disconnected from the power supply voltage V_{SS} through the switch transistor MPB of the response circuit 214b.

Of course, the circuitry structure of the detector 210 in the example of FIG. 2B or in the example of FIG. 2C may be modified. For example, in a third exemplary detector 210, the control circuit 212a of FIG. 2B is connected with the response circuit 214b of FIG. 2C. Similarly, in a fourth exemplary detector 210, the control circuit 212b of FIG. 2C is connected with the response circuit 214a of FIG. 2B. In some other examples of the detector 210, the pull-down circuits 216a and 216b in FIG. 2B and FIG. 2C may be exchanged.

In the first embodiment of the bandgap reference circuit, the detector 210 detects whether the bias voltage V_{D} from the output terminal of the operation amplifier 15 (i.e., the bias node d) is abnormal, and the response circuit 214 of the detector 210 dynamically adjusts the bias voltage V_{D} at the bias node d. In some other embodiments, the detector 210 detects the voltage at another node and dynamically adjusts the bias voltage V_{D} at the bias node d.

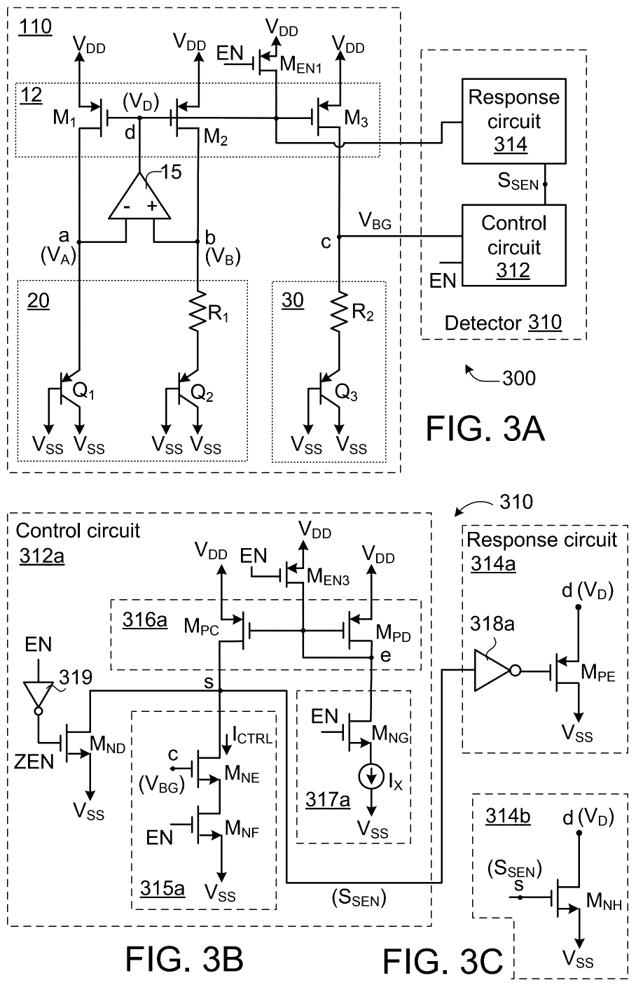

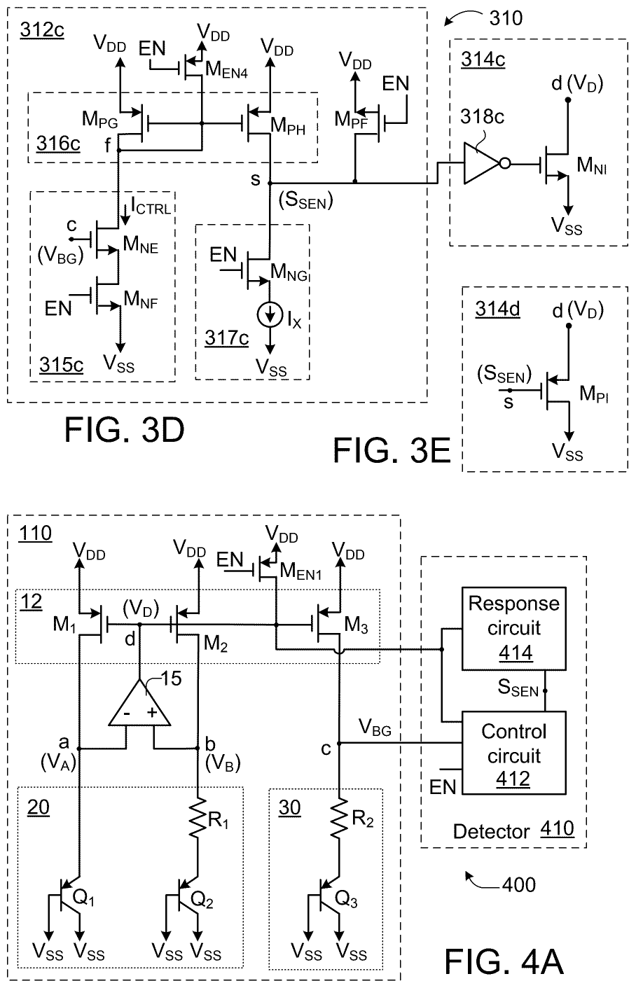

FIG. 3A is a schematic circuit diagram illustrating a bandgap reference circuit according to a second embodiment of the present invention. As shown in FIG. 3A, the bandgap reference circuit 300 includes a bandgap voltage generator 110 and a detector 310. The circuitry structure of the bandgap voltage generator 110 of this embodiment is similar to that of the above, and not redundantly described herein.

As shown in FIG. 3A, the detector 310 includes a control circuit 312 and a response circuit 314. When the enable signal EN is not activated, the detector 310 is disabled. When the enable signal EN is activated, the detector 310 is enabled.

The control circuit 312 receives the enable signal EN. The control circuit 312 is connected with the node c of the bandgap voltage generator 110 to detect the change of the bandgap voltage VBG and generate a sensing signal S_{SEN} to the response circuit 314. The response circuit 314 is connected with the bias node d of the bandgap voltage generator 110. In addition, the response circuit 314 appropriately adjusts the bias voltage V_{D} at the bias node d according to the sensing signal S_{SEN}.

For example, in case that the power noise or the ground noise is large, the bandgap voltage VBG at the node c decreases, and the bias voltage V_{D} at the bias node d increases. According to the change of the bandgap voltage VBG, the control circuit 312 selectively activates the sensing signal S_{SEN}. Consequently, the response circuit 314 decreases the bias voltage V_{D} at the bias node d. Hereinafter, some examples of the detector 310 in the bandgap reference circuit 300 of the second embodiment will be described.

FIG. 3B is a schematic circuit diagram illustrating a first exemplary detector of the bandgap reference circuit according to the second embodiment of the present invention. The detector 310 includes a control circuit 312a and a response circuit 314a. The control circuit 312a includes a P-type FET transistor M_{EN3}, an N-type FET transistor M_{ND}, a current mirror 316a, and two current control paths 315a and 317a. The response circuit 314a includes a P-type FET transistor M_{PE} and an inverter 318a. The transistor M_{PE} can be regarded as a switch transistor.

In the response circuit 314a, the input terminal of the inverter 318a is connected with the sensing node s, the source terminal of the transistor M_{PE} is connected with the bias node d, the drain terminal of the transistor M_{PE} receives the power supply voltage V_{SS}, and the gate terminal of the transistor M_{PE} is connected with the output terminal of the inverter 318a.

In the control circuit 312a, the source terminal of the transistor M_{EN3} receives the power supply voltage V_{DD}, the drain terminal of the transistor M_{EN3} is connected with the node e, the gate terminal of the transistor M_{EN3} receives the enable signal EN, the drain terminal of the transistor M_{ND} is connected with the sensing node s, the source terminal of the transistor M_{ND} receives the power supply voltage V_{SS}, and the gate terminal of the transistor M_{ND} receives an inverted enable signal ZEN. The enable signal EN and the inverted enable signal ZEN are complementary to each other. For example, an inverter 319 receives the enable signal EN and generates the inverted enable signal ZEN.

The current mirror 316a includes P-type FET transistors M_{PC} and M_{PD}. The source terminal of the transistor M_{PD} receives the power supply voltage V_{DD}. The drain terminal of the transistor M_{PD} is connected with the node e. The gate terminal of the transistor M_{PD} is connected with the node e. The source terminal of the transistor M_{PC} receives the power supply voltage V_{DD}. The drain terminal of the transistor M_{PC} is connected with the sensing node s. The gate terminal of the transistor M_{PC} is connected with the node e. The node e is a current input terminal of the current mirror 316a. The sensing node s is a current mirroring terminal of the current mirror 316a.

The current control path 317a includes an N-type FET transistor M_{NG} and a current source Ix. The drain terminal of the transistor M_{NG} is connected with the node e. The gate terminal of the transistor M_{NG} receives the enable signal EN. The first terminal of the current source Ix is connected with the source terminal of the transistor M_{NG}. The second terminal of the current source Ix receives the power supply voltage V_{SS}. The current source Ix generates a constant current Ix.

The current control path 315a includes N-type FET transistors MNE and M_{NF}. The drain terminal of the transistor M_{NE} is connected with the sensing node s. The gate terminal of the transistor M_{NE} is connected with the node c in the bandgap voltage generator 110. The drain terminal of the transistor M_{NF} is connected to the source terminal of the transistor M_{NE}. The gate terminal of the transistor M_{NF} receives the enable signal EN. The source terminal of the transistor M_{NF} receives the power supply voltage V_{SS}.

Please refer to FIG. 3B. When the enable signal EN is not activated (i.e., in the low logic level state), the detector 310 is disabled. When the enable signal EN is activated (i.e., in the high logic level state), the inverted enable signal ZEN is in the low logic level state. Consequently, the transistor M_{ND} and the transistor M_{EN3} are turned off, and the transistor M_{NF} and the transistor M_{NG} are turned on. Under this circumstance, the control current I_{CTRL} generated by the transistor M_{PA} can be controlled according to the bandgap voltage VBG at the node c. As the control current I_{CTRL} is changed, the voltage level of the sensing signal S_{SEN} is correspondingly changed.

When the bandgap voltage generator 110 is operated normally, the transistor M_{NE} is controlled according to the bandgap voltage VBG. Consequently, the control current I_{CTRL} is approximately equal to the current Ix. Meanwhile, the voltage level of the sensing signal S_{SEN} is less than the voltage level of a transition point of the inverter 318a. It means that the sensing signal S_{SEN} is not activated. The voltage at the output terminal of the inverter 318a is in the high logic level state. Consequently, the transistor M_{PE} is turned off.

In case that the power noise or the ground noise is large, the bandgap voltage VBG decreases. Consequently, the control current I_{CTRL} decreases. Correspondingly, the voltage level of the sensing signal S_{SEN} increases. If the voltage level of the sensing signal S_{SEN} is greater than the voltage level of the transition point of the inverter 318a, it means that the sensing signal S_{SEN} is activated. The output terminal of the inverter 318a is changed to the low logic level state. Consequently, the transistor M_{PE} is turned on. Under this circumstance, the bias node d is connected with the power supply voltage V_{SS} through the switch transistor M_{PE} of the response circuit 314a. Consequently, the response circuit 314a stops increasing the bias voltage V_{D} continuously and decreases the bias voltage V_{D}. The bandgap voltage generator 110 is restored to the normal operation.

When the bandgap voltage generator 110 is restored to the normal operation, the sensing signal S_{SEN} is inactivated. Consequently, the transistor M_{PE} is turned off, and the bias node d is disconnected from the power supply voltage V_{SS} through the switch transistor M_{PE} of the response circuit 314a.

FIG. 3C is a schematic circuit diagram illustrating another response circuit in the detector of the bandgap reference circuit according to the second embodiment of the present invention. Like the above embodiment, the two response circuits 214a and 214b in FIGS. 2B and 2C may be exchanged. In a second exemplary detector 310, the control circuit 312a of FIG. 3B is connected with the response circuit 314b of FIG. 3C.

The response circuit 314b includes an N-type FET transistor MNH. The drain terminal of the transistor MNH is connected with the bias node d. The source terminal of the transistor MNH receives the power supply voltage V_{SS}. The gate terminal of the transistor MNH is connected with the sensing node s.

In case that the power noise or the ground noise is large, the bandgap voltage VBG decreases. Consequently, the control current I_{CTRL} decreases. Correspondingly, the voltage level of the sensing signal S_{SEN} increases. If the voltage level of the sensing signal S_{SEN} is greater than a threshold voltage of the transistor MNH, the sensing signal S_{SEN} is activated, and the transistor MNH is turned on. Under this circumstance, the bias node d is connected with the power supply voltage V_{SS} through the switch transistor MNH of the response circuit 314b. Consequently, the response circuit 314b stops increasing the bias voltage V_{D} continuously and decreases the bias voltage V_{D}. The bandgap voltage generator 110 is restored to the normal operation.

FIG. 3D is a schematic circuit diagram illustrating a third exemplary detector of the bandgap reference circuit according to the second embodiment of the present invention. The detector 310 includes a control circuit 312c and a response circuit 314c.

The control circuit 312c includes a P-type FET transistor M_{EN4}, a P-type FET transistor M_{PF}, a current mirror 316c, and two current control paths 315c and 317c. The response circuit 314c includes an N-type FET transistor M_{NI} and an inverter 318c. The circuitry structures of the current control paths 315c and 317c are similar to those of the current control paths 315a and 317a shown in FIG. 3A, and not redundantly described herein.

In the response circuit 314c, the input terminal of the inverter 318c is connected with the sensing node s, the drain terminal of the transistor M_{NI} is connected with the bias node d, the source terminal of the transistor M_{NI} receives the power supply voltage V_{SS}, and the gate terminal of the transistor M_{NI} is connected with the output terminal of the inverter 318c. The transistor M_{NI} may be regarded as a switch transistor.

In the control circuit 312c, the source terminal of the transistor M_{EN4} receives the power supply voltage V_{DD}, the drain terminal of the transistor M_{EN4} is connected with the node f, the gate terminal of the transistor M_{EN4} receives the enable signal EN, the source terminal of the transistor M_{PF} receives the power supply voltage V_{DD}, the drain terminal of the transistor M_{PF} is connected with the sensing node s, and the gate terminal of the transistor M_{PF} receives the enable signal EN.

The current mirror 316c includes P-type FET transistors MPG and MPH. The source terminal of the transistor MPG receives the power supply voltage V_{DD}. The drain terminal of the transistor MPG is connected with the node f. The gate terminal of the transistor MPG is connected with the node f. The source terminal of the transistor MPH receives the power supply voltage V_{DD}. The drain terminal of the transistor MPH is connected with the sensing node s. The gate terminal of the transistor MPH is connected with the node f. The node f is a current input terminal of the current mirror 316c. The sensing node s is a current mirroring terminal of the current mirror 316c. The current control path 315c is connected between the node f and the power supply voltage V_{SS}. The current control path 317c is connected between the sensing node s and the power supply voltage V_{SS}.

Please refer to FIG. 3D. When the enable signal EN is not activated (i.e., in the low logic level state), the detector 310 is disabled. When the enable signal EN is activated (i.e., in the high logic level state), the transistor M_{PF} and the transistor M_{EN4} are turned off, and the transistor M_{NF} and the transistor M_{NG} are turned on. Under this circumstance, the control current I_{CTRL} generated by the transistor M_{NE} can be controlled according to the bandgap voltage V_{BG} at the node c. As the control current I_{CTRL} is changed, the voltage level of the sensing signal S_{SEN} is correspondingly changed.

When the bandgap voltage generator 110 is operated normally, the transistor M_{NE} is controlled according to the bandgap voltage V_{BG}. Consequently, the control current I_{CTRL} is approximately equal to the current Ix. Meanwhile, the voltage level of the sensing signal S_{SEN} is greater than the voltage level of a transition point of the inverter 318c. It means that the sensing signal S_{SEN} is not activated. The voltage at the output terminal of the inverter 318c is in the low logic level state. Consequently, the transistor M_{NI} is turned off.

In case that the power noise or the ground noise is large, the bandgap voltage V_{BG} decreases. Consequently, the control current I_{CTRL} decreases. Correspondingly, the voltage level of the sensing signal S_{SEN} decreases. If the voltage level of the sensing signal S_{SEN} is less than the voltage level of the transition point of the inverter 318a, it means that the sensing signal S_{SEN} is activated.

The output terminal of the inverter 318a is changed to the high logic level state. Consequently, the transistor M_{NI} is turned on. Under this circumstance, the bias node d is connected with the power supply voltage V_{SS} through the switch transistor M_{NI} of the response circuit 314c. Consequently, the response circuit 314c stops increasing the bias voltage V_{D} continuously and decreases the bias voltage V_{D}. The bandgap voltage generator 110 is restored to the normal operation.

When the bandgap voltage generator 110 is restored to the normal operation, the sensing signal S_{SEN} is inactivated. Consequently, the transistor M_{NI} is turned off, and the bias node d is disconnected from the power supply voltage V_{SS} through the switch transistor M_{NI} of the response circuit 314c.

FIG. 3E is a schematic circuit diagram illustrating another response circuit in the detector of the bandgap reference circuit according to the second embodiment of the present invention. Like the above embodiment, the two response circuits 214a and 214b in FIGS. 2B and 2C may be exchanged. In a fourth exemplary detector 310, the control circuit 312c of FIG. 3D is connected with the response circuit 314d of FIG. 3E.

The response circuit 314d includes a P-type FET transistor M_{PI}. The source terminal of the transistor M_{PI} is connected with the bias node d. The drain terminal of the transistor M_{PI} receives the power supply voltage V_{SS}. The gate terminal of the transistor M_{PI} is connected with the sensing node s.

In case that the power noise or the ground noise is large, the bandgap voltage V_{BG} decreases. Consequently, the control current I_{CTRL} decreases. Correspondingly, the voltage level of the sensing signal S_{SEN} increases. If the voltage difference between the sensing signal S_{SEN} and the bias voltage V_{D} is less than a threshold voltage of the transistor M_{PI}, the sensing signal S_{SEN} is activated, and the transistor M_{PI} is turned on. Under this circumstance, the bias node d is connected with the power supply voltage V_{SS} through the switch transistor M_{PI} of the response circuit 314d. Consequently, the response circuit 314d stops increasing the bias voltage V_{D} continuously and decreases the bias voltage V_{D}. The bandgap voltage generator 110 is restored to the normal operation.

In the second embodiment of the bandgap reference circuit, the detector 310 detects whether the bandgap voltage V_{BG} at the node c is abnormal, and the response circuit 314 of the detector 310 dynamically adjusts the bias voltage V_{D} at the bias node d. In some other embodiments, the detector 310 detects the voltage difference between the node c and the node d and dynamically adjusts the bias voltage V_{D} at the bias node d.

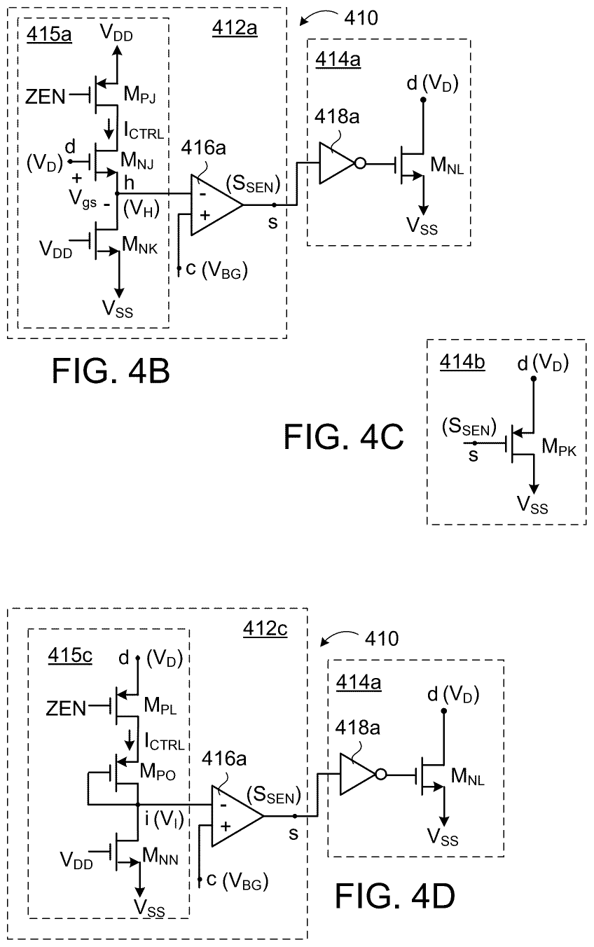

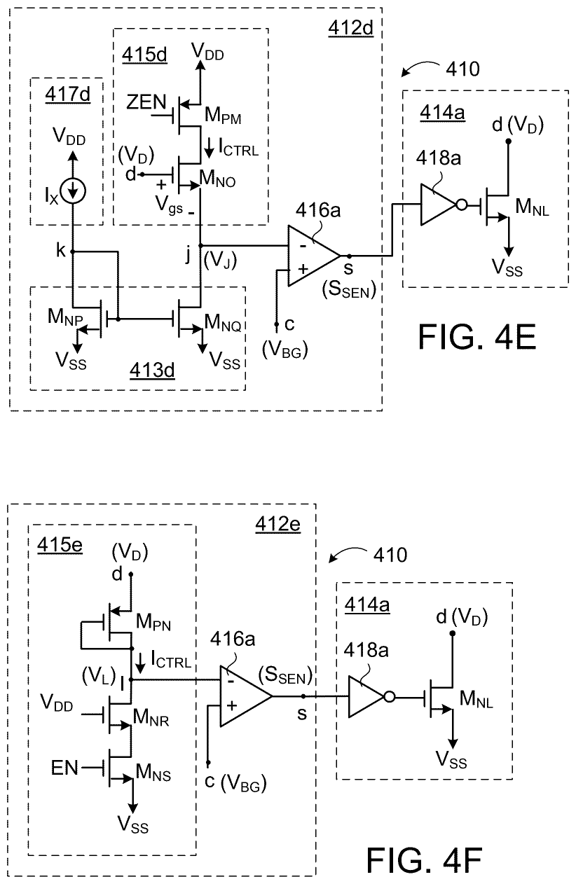

FIG. 4A is a schematic circuit diagram illustrating a bandgap reference circuit according to a third embodiment of the present invention. As shown in FIG. 4A, the bandgap reference circuit 400 includes a bandgap voltage generator 110 and a detector 410. The detector 410 includes a control circuit 412 and a response circuit 414. When the enable signal EN is not activated, the detector 410 is disabled. When the enable signal EN is activated, the detector 410 is enabled.

The control circuit 412 receives the enable signal EN. The control circuit 412 is connected with the node c and the node d of the bandgap voltage generator 110 to detect the change of the bandgap voltage V_{BG} and generate a sensing signal S_{SEN} to the response circuit 414. The response circuit 414 is connected with the bias node d of the bandgap voltage generator 110. When the sensing signal S_{SEN} is activated, the response circuit 414 appropriately adjusts the bias voltage V_{D} at the bias node d.

For example, in case that the power noise or the ground noise is large, the bandgap voltage V_{BG} at the node c decreases, and the bias voltage V_{D} at the bias node d increases. According to the changes of the bias voltage V_{D} and the bandgap voltage V_{BG}, the control circuit 412 selectively activates the sensing signal S_{SEN}. Consequently, the response circuit 414 decreases the bias voltage V_{D} at the bias node d. Hereinafter, some examples of the detector 410 in the bandgap reference circuit 400 of the third embodiment will be described.

FIG. 4B is a schematic circuit diagram illustrating a first exemplary detector of the bandgap reference circuit according to the third embodiment of the present invention. The detector 410 includes a control circuit 412a and a response circuit 414a. The control circuit 412a includes a current control path 415a and a comparator 416a. The current control path 415a includes a P-type FET transistor M_{PJ}, an N-type FET transistor M_{NJ} and an N-type FET transistor M_{NK}. The response circuit 414a includes an N-type FET transistor M_{NL} and an inverter 418a.

In the response circuit 414a, the input terminal of the inverter 418a is connected with the sensing node s, the drain terminal of the transistor M_{NL} is connected with the bias node d, the source terminal of the transistor M_{NL} receives the power supply voltage V_{SS}, and the gate terminal of the transistor M_{NL} is connected with the output terminal of the inverter 418a. The transistor M_{NL} may be regarded as a switch transistor.

In the current control path 415a of the control circuit 412a, the source terminal of the transistor M_{PJ} receives the power supply voltage V_{DD}, and the gate terminal of the transistor M_{PJ} receives an inverted enable signal ZEN. The drain terminal of the transistor M_{NJ} is connected with the drain terminal of the transistor M_{PJ}. The source terminal of the transistor M_{NJ} is connected with the node h. The gate terminal of the transistor M_{NJ} is connected with the bias node d. The drain terminal of the transistor M_{NK} is connected with the node h. The source terminal of the transistor M_{NK} receives the power supply voltage V_{SS}. The gate terminal of the transistor M_{NJ} receives the power supply voltage V_{DD}. A positive input terminal of the comparator 416a is connected with the node c. A negative input terminal of the comparator 416a is connected with the node h. An output terminal of the comparator 416a is connected with the sensing node s to generate a sensing signal S_{SEN}. The transistor M_{NK} is a weak N-type FET transistor. The size of the transistor M_{NK} is smaller than that of the transistor M_{NJ}. The internal resistance of the transistor M_{NK} is greater than that of the transistor M_{NJ}.

Please refer to FIG. 4B. When the enable signal EN is not activated (i.e., in the low logic level state), the detector 410 is disabled. When the enable signal EN is activated (i.e., in the high logic level state), the inverted enable signal ZEN is in the low logic level state. Consequently, the transistor M_{PJ} is turned on. Under this circumstance, the control current I_{CTRL} generated by the transistor M_{NJ} can be controlled according to the bias voltage V_{D} at the bias node d. As the control current I_{CTRL} is changed, the voltage V_{H} at the node h is correspondingly changed.

When the bandgap voltage generator 110 is operated normally, the voltage V_{H} at the node h is (V_{D}−V_{gs}), wherein V_{gs} is the gate-source voltage of the transistor M_{NJ}. The voltage V_{H} at the node h is less than the bandgap voltage V_{BG}. Meanwhile, the sensing signal S_{SEN} outputted from the output terminal of the comparator 416a is in the high logic level state, indicating that the sensing signal S_{SEN} is not activated. The voltage at the output terminal of the inverter 418a is in the low logic level state. Consequently, the transistor M_{NL} is turned off.

In case that the power noise or the ground noise is large, the bandgap voltage V_{BG} decreases, and the bias voltage V_{D} increases. Since the bias voltage V_{D} increases, the control current I_{CTRL} increases, and the voltage V_{H} at the node h increases. If the voltage V_{H} at the node h is greater than the bandgap voltage V_{BG}, the sensing signal S_{SEN} outputted from the output terminal of the comparator 416a is in the low logic level state, indicating that the sensing signal S_{SEN} is activated. The output terminal of the inverter 418a is changed to the high logic level state. Consequently, the transistor M_{NL} is turned on. Under this circumstance, the bias node d is connected with the power supply voltage V_{SS} through the switch transistor M_{NL} of the response circuit 414a. Consequently, the response circuit 414a stops increasing the bias voltage V_{D} continuously and decreases the bias voltage V_{D}. The bandgap voltage generator 110 is restored to the normal operation.

When the bandgap voltage generator 110 is restored to the normal operation, the sensing signal S_{SEN} is inactivated. Consequently, the transistor M_{NL} is turned off, and the bias node d is disconnected from the power supply voltage V_{SS} through the switch transistor M_{NL} of the response circuit 414a.

FIG. 4C is a schematic circuit diagram illustrating another response circuit in the detector of the bandgap reference circuit according to the third embodiment of the present invention. Like the above embodiment, the two response circuits 214a and 214b in FIGS. 2B and 2C may be exchanged. In a second exemplary detector 410, the control circuit 412a of FIG. 4B is connected with the response circuit 414b of FIG. 4C.

The response circuit 414b includes a P-type FET transistor M_{PK}. The source terminal of the transistor M_{PK} is connected with the bias node d. The drain terminal of the transistor M_{PK} receives the power supply voltage V_{SS}. The gate terminal of the transistor M_{PK} is connected with the sensing node s. The transistor M_{PK} may be regarded as a switch transistor.

In case that the power noise or the ground noise is large, sensing signal S_{SEN} outputted from the output terminal of the comparator 416a is in the low logic level state, indicating that the sensing signal S_{SEN} is activated. Consequently, the transistor M_{PK} is turned on. Under this circumstance, the bias node d is connected with the power supply voltage V_{SS} through the switch transistor M_{PK} of the response circuit 414b. Consequently, the response circuit 414b stops increasing the bias voltage V_{D} continuously and decreases the bias voltage V_{D}. The bandgap voltage generator 110 is restored to the normal operation.

FIG. 4D is a schematic circuit diagram illustrating a third exemplary detector of the bandgap reference circuit according to the third embodiment of the present invention. The detector 410 includes a control circuit 412c and a response circuit 414c. The control circuit 412c includes a current control path 415c and a comparator 416a. For succinctness, only the current control path 415c will be described as follows.

In the current control path 415c of the control circuit 412c, the source terminal of the transistor M_{PL} is connected with the bias node d to receive the bias voltage V_{D}, the gate terminal of the transistor M_{PL} receives an inverted enable signal ZEN, the source terminal of the transistor M_{PO} is connected with the drain terminal of the transistor M_{PL}, the drain terminal of the transistor M_{PO} is connected with the node i, and the gate terminal of the transistor M_{PO} is connected with the node i. In addition, the transistor M_{PO} is a diode-connected transistor. The drain terminal of the transistor M_{NN} is connected with the node i. The source terminal of the transistor M_{NN} receives the power supply voltage V_{SS}. The gate terminal of the transistor M_{NN} receives the power supply voltage V_{DD}. A positive input terminal of the comparator 416a is connected with the node c. A negative input terminal of the comparator 416a is connected with the node i. An output terminal of the comparator 416a is connected with the sensing node s to generate a sensing signal S_{SEN}. The transistor M_{NN} is a weak N-type FET transistor.

Please refer to FIG. 4D. When the enable signal EN is not activated (i.e., in the low logic level state), the detector 410 is disabled. When the enable signal EN is activated (i.e., in the high logic level state), the inverted enable signal ZEN is in the low logic level state. Consequently, the transistor M_{PL} is turned on. Under this circumstance, the voltage V_{H} at the node h is controlled according to the bias voltage V_{D} at the node d.

When the bandgap voltage generator 110 is operated normally, the voltage V_{I} at the node i is (V_{D}-V_{T}), wherein V_{T} is the threshold voltage of the transistor MNM. The voltage V_{I} at the node i is less than the bandgap voltage V_{BG}. Meanwhile, the sensing signal S_{SEN} outputted from the output terminal of the comparator 416a is in the high logic level state. It mean that the sensing signal S_{SEN} is not activated. The voltage at the output terminal of the inverter 418a is in the low logic level state. Consequently, the transistor M_{NL} is turned off.

In case that the power noise or the ground noise is large, the bandgap voltage V_{BG} decreases, and the bias voltage V_{D} increases. Since the bias voltage V_{D} increases, the control current I_{CTRL} increases, and the voltage V_{I} at the node i increases. If the voltage V_{I} at the node i is greater than the bandgap voltage V_{BG}, the sensing signal S_{SEN} outputted from the output terminal of the comparator 416a is in the low logic level state, indicating that the sensing signal S_{SEN} is activated. The output terminal of the inverter 418a is changed to the high logic level state. Consequently, the transistor M_{NL} is turned on. Under this circumstance, the bias node d is connected with the power supply voltage V_{SS} through the switch transistor M_{NL} of the response circuit 414a. Consequently, the response circuit 414a stops increasing the bias voltage V_{D} continuously and decreases the bias voltage V_{D}. The bandgap voltage generator 110 is restored to the normal operation.

When the bandgap voltage generator 110 is restored to the normal operation, the sensing signal S_{SEN} is inactivated. Consequently, the transistor M_{NL} is turned off, and the bias node d is disconnected from the power supply voltage V_{SS} through the switch transistor M_{NL} of the response circuit 414a.

In a fourth exemplary detector 410, the control circuit 412a of FIG. 4D is connected with the response circuit 414b of FIG. 4C.

FIG. 4E is a schematic circuit diagram illustrating a fifth exemplary detector of the bandgap reference circuit according to the third embodiment of the present invention. The detector 410 includes a control circuit 412d and a response circuit 414a. For succinctness, only the control circuit 412d will be described herein. The control circuit 412d includes a current mirror 413d, a comparator 416a, and two current control paths 415d and 417d.

The current mirror 413d includes N-type FET transistors M_{NP} and M_{NQ}. The source terminal of the transistor M_{NP} receives the power supply voltage V_{SS}. The drain terminal of the transistor M_{NP} is connected with the node k. The gate terminal of the transistor M_{NP} is connected with the node k. The source terminal of the transistor M_{NQ} receives the power supply voltage V_{SS}. The drain terminal of the transistor M_{NQ} is connected with the sensing node j. The gate terminal of the transistor M_{NQ} is connected with the node k. The node k is a current input terminal of the current mirror 413d. The sensing node j is a current mirroring terminal of the current mirror 413d.

The current control path 417d includes a current source I_{X}. The current source I_{X} is connected between the power supply voltage V_{DD} and the node k. The current source I_{X} generates a constant current I_{X}.

The current control path 415a includes a P-type FET transistor M_{PM} and an N-type FET transistor M_{NQ}. The source terminal of the transistor M_{PM} receives the power supply voltage V_{DD}. The gate terminal of the transistor M_{PM} receives the inverted enable signal ZEN. The drain terminal of the transistor M_{NO} is connected with the drain terminal of the transistor M_{PM}. The gate terminal of the transistor M_{NO} is connected with the bias node d. The source terminal of the transistor M_{NO} is connected with the node j. A positive input terminal of the comparator 416a is connected with the node c. A negative input terminal of the comparator 416a is connected with the node j. An output terminal of the comparator 416a is connected with the sensing node s to generate a sensing signal S_{SEN}.

Please refer to FIG. 4E. When the enable signal EN is not activated (i.e., in the low logic level state), the detector 410 is disabled. When the enable signal EN is activated (i.e., in the high logic level state), the inverted enable signal ZEN is in the low logic level state. Consequently, the transistor M_{PM} is turned on. Under this circumstance, the voltage V_{J} at the node j can be controlled according to the bias voltage V_{D} at the node d.

When the bandgap voltage generator 110 is operated normally, the voltage V_{J} at the node j is (V_{D}−V_{gs}), wherein V_{gs} is the gate-source voltage of the transistor MNO. The voltage V_{J} at the node j is less than the bandgap voltage V_{BG}. Meanwhile, the sensing signal S_{SEN} outputted from the output terminal of the comparator 416a is in the high logic level state, indicating that the sensing signal S_{SEN} is not activated. The voltage at the output terminal of the inverter 418a is in the low logic level state. Consequently, the transistor M_{NL} is turned off.

In case that the power noise or the ground noise is large, the bandgap voltage V_{BG} decreases, and the bias voltage V_{D} increases. Since the bias voltage V_{D} increases, the control current I_{CTRL} increases, and the voltage V_{J} at the node j increases. If the voltage V_{J} at the node j is greater than the bandgap voltage V_{BG}, the sensing signal S_{SEN} outputted from the output terminal of the comparator 416a is in the low logic level state, indicating that the sensing signal S_{SEN} is activated. The output terminal of the inverter 418a is changed to the high logic level state. Consequently, the transistor M_{NL} is turned on. Under this circumstance, the bias node d is connected with the power supply voltage V_{SS} through the switch transistor M_{NL} of the response circuit 414a. Consequently, the response circuit 414a stops increasing the bias voltage V_{D} continuously and decreases the bias voltage V_{D}. The bandgap voltage generator 110 is restored to the normal operation.

When the bandgap voltage generator 110 is restored to the normal operation, the sensing signal S_{SEN} is inactivated. Consequently, the transistor M_{NL} is turned off, and the bias node d is disconnected from the power supply voltage V_{SS} through the switch transistor M_{NL} of the response circuit 414a.

In a sixth exemplary detector 410, the control circuit 412d of FIG. 4E is connected with the response circuit 414b of FIG. 4C.

FIG. 4F is a schematic circuit diagram illustrating a seventh exemplary detector of the bandgap reference circuit according to the third embodiment of the present invention.

The detector 410 includes a control circuit 412e and a response circuit 414e. The control circuit 412e includes a current control path 415e and a comparator 416e. The current control path 415e includes a P-type FET transistor M_{PN}, an N-type FET transistor MNR and an N-type FET transistor M_{ND}. For succinctness, only the current control path 415e will be described as follows.

In the current control path 415e of the control circuit 412e, the source terminal of the transistor M_{PN} is connected with the bias node d to receive the bias voltage V_{D}, the gate terminal of the transistor M_{PN} is connected with the node I, and the drain terminal of the transistor M_{PN} is connected with the node I. The transistor M_{PN} is a diode-connected transistor. The drain terminal of the transistor M_{NR} is connected with the node I. The gate terminal of the transistor M_{NR} receives the power supply voltage V_{DD}. The drain terminal of the transistor M_{NS} is connected with the source terminal of the transistor M_{NR}. The source terminal of the transistor M_{NS} receives the power supply voltage V_{SS}. The gate terminal of the transistor M_{NS} receives the enable signal EN. A positive input terminal of the comparator 416a is connected with the node c. A negative input terminal of the comparator 416a is connected with the node I. An output terminal of the comparator 416a is connected with the sensing node s to generate a sensing signal S_{SEN}. The transistor M_{NR} is a weak N-type FET transistor.

Please refer to FIG. 4F. When the enable signal EN is not activated (i.e., in the low logic level state), the sensing signal S_{SEN} at the sensing node s can be changed, indicating that the detector 410 is disabled. When the enable signal EN is activated (i.e., in the high logic level state), the transistor M_{NS} is turned on. Under this circumstance, the voltage V_{L} at the node I is controlled according to the bias voltage V_{D} at the node d.

When the bandgap voltage generator 110 is operated normally, the voltage V_{L} at the node I is (V_{D}−V_{T}), wherein V_{T} is the threshold voltage of the transistor MNM. The voltage V_{L} at the node I is less than the bandgap voltage V_{BG}. Meanwhile, the sensing signal S_{SEN} outputted from the output terminal of the comparator 416a is in the high logic level state. It means that the sensing signal S_{SEN} is not activated. The voltage at the output terminal of the inverter 418a is in the low logic level state. Consequently, the transistor M_{NL} is turned off.

In case that the power noise or the ground noise is large, the bandgap voltage V_{BG} decreases, and the bias voltage V_{D} increases. Since the bias voltage V_{D} increases, the control current I_{CTRL} increases, and the voltage V_{I} at the node I increases. If the voltage V_{L} at the node I is greater than the bandgap voltage V_{BG}, the sensing signal S_{SEN} outputted from the output terminal of the comparator 416a is in the low logic level state, indicating that the sensing signal S_{SEN} is activated. The output terminal of the inverter 418a is changed to the high logic level state. Consequently, the transistor M_{NL} is turned on. Under this circumstance, the bias node d is connected with the power supply voltage V_{SS} through the switch transistor M_{NL} of the response circuit 414a. Consequently, the response circuit 414a stops increasing the bias voltage V_{D} continuously and decreases the bias voltage V_{D}. The bandgap voltage generator 110 is restored to the normal operation.

When the bandgap voltage generator 110 is restored to the normal operation, the sensing signal S_{SEN} is inactivated. Consequently, the transistor M_{NL} is turned off, and the bias node d is disconnected from the power supply voltage V_{SS} through the switch transistor M_{NL} of the response circuit 414a.

In an eighth exemplary detector 410, the control circuit 412e of FIG. 4F is connected with the response circuit 414b of FIG. 4C.

In case that one of the detectors 210, 310, and 410 in the bandgap voltage generator 110 of the above embodiments fails, the control circuit 212, 312 or 412 activates the sensing signal S_{SEN}. Consequently, the bias node d in the bandgap voltage generator 110 is connected with the power supply voltage V_{SS} through the response circuit 214, 314 or 414. In this way, the bandgap voltage generator 110 is forced to be restored to the normal operation.

In some other embodiments, another node in the bandgap voltage generator 110 can be connected to the corresponding power supply voltage through the detector of the present invention. Consequently, the bandgap voltage generator 110 is forced to be restored to the normal operation.

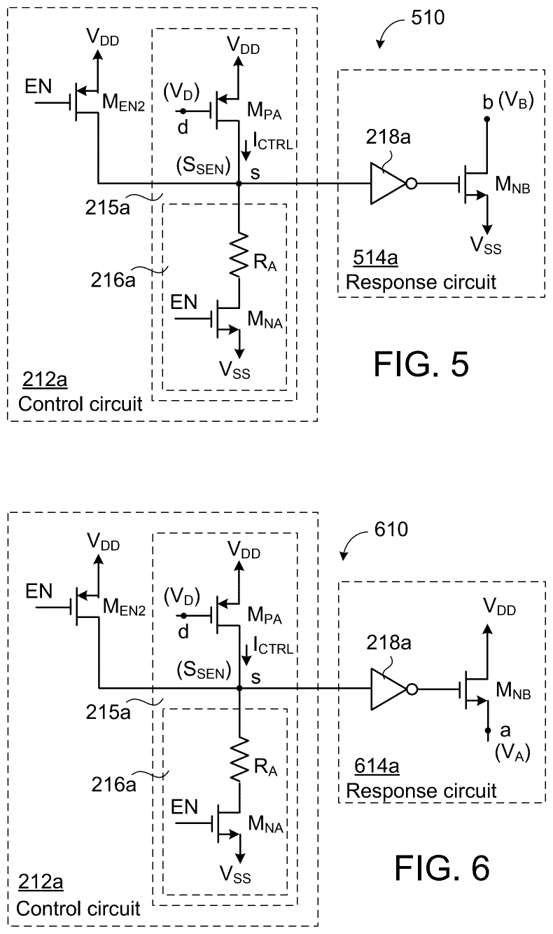

For example, when the bandgap voltage generator 110 fails, the voltage VB at the node b increases. In this design, the node b is connected to the power supply voltage V_{SS} through the response circuit. Consequently, the bandgap voltage generator 110 is forced to be restored to the normal operation. An example of the detector will be illustrated with reference to FIG. 5.

FIG. 5 is a schematic circuit diagram illustrating an exemplary detector of a bandgap reference circuit according to a fourth embodiment of the present invention. As shown in FIG. 5, the bandgap reference circuit includes a bandgap voltage generator 110 and a detector 510. In comparison with the detector 210 shown in FIG. 2B, the drain terminal of the switch transistor M_{NB} in the detector 510 of the bandgap reference circuit of the fourth embodiment is connected with the node b. The connecting relationships between other components are similar, and not redundantly described herein.

In case that the power noise or the ground noise is large, the voltage V_{D} from the output terminal of the operation amplifier 15 (i.e., the bias node d) in the bandgap voltage generator 110 increases. Consequently, the control current I_{CTRL} decreases. Correspondingly, the voltage level of the sensing signal S_{SEN} decreases. If the voltage level of the sensing signal S_{SEN} is less than the voltage level of the transition point of the inverter 218a, the sensing signal S_{SEN} is activated. The output terminal of the inverter 218a is changed to the high logic level state. In addition, the transistor M_{NB} is turned on. Under this circumstance, the bias node b is connected with the power supply voltage V_{SS} through the switch transistor M_{NB} of the response circuit 514a. Consequently, the response circuit 514a stops increasing the voltage V_{b} at the node b continuously and decreases the voltage VB at the node b. The bandgap voltage generator 110 is restored to the normal operation.

Similarly, the detectors 210, 310 and 410 in the above embodiments may be modified. For example, the response circuit 214a, 214b, 314a, 314b, 314c, 314d, 414a or 414b is connected with the node b instead of being connected with the node d. Consequently, the bandgap voltage generator 110 is forced to be restored to the normal operation.

For example, when the bandgap voltage generator 110 fails, the voltage VA at the node a decreases. In this design, the node a is connected to the power supply voltage V_{DD} through the response circuit. Consequently, the bandgap voltage generator 110 is forced to be restored to the normal operation. An example of the detector will be illustrated with reference to FIG. 6.

FIG. 6 is a schematic circuit diagram illustrating an exemplary detector of a bandgap reference circuit according to a fifth embodiment of the present invention. As shown in FIG. 6, the bandgap reference circuit includes a bandgap voltage generator 110 and a detector 610.

In comparison with the detector 210 shown in FIG. 2B, the drain terminal of the switch transistor M_{NB} in the detector 610 of the bandgap reference circuit of the fifth embodiment receives the power supply voltage V_{DD}, and the source terminal of the switch transistor M_{NB} is connected with the node a. The connecting relationships between other components are similar, and not redundantly described herein.

In case that the power noise or the ground noise is large, the voltage V_{D} from the output terminal of the operation amplifier 15 (i.e., the bias node d) in the bandgap voltage generator 110 increases. Consequently, the control current I_{CTRL} decreases. Correspondingly, the voltage level of the sensing signal S_{SEN} decreases. If the voltage level of the sensing signal S_{SEN} is less than the voltage level of the transition point of the inverter 218a, the sensing signal S_{SEN} is activated. The output terminal of the inverter 218a is changed to the high logic level state. In addition, the transistor M_{NB} is turned on. Under this circumstance, the bias node a is connected with the power supply voltage V_{DD} through the switch transistor M_{NB} of the response circuit 614a. Consequently, the response circuit 614a stops decreasing the voltage VA at the node a continuously and increases the voltage VA at the node a. The bandgap voltage generator 110 is restored to the normal operation.

Similarly, the detectors 210, 310 and 410 in the above embodiments may be modified. For example, the response circuit 214a, 214b, 314a, 314b, 314c, 314d, 414a or 414b is connected between the node a and the power supply voltage V_{DD} through the switch transistor M_{NB}, MPB, M_{PE}, MNH, M_{NI}, M_{PI}, M_{NL} or M_{PK}. Consequently, the bandgap voltage generator 110 is forced to be restored to the normal operation.

From the above descriptions, the detector of the present invention includes a control circuit and a response circuit. The control circuit is connected with at least one of the bias node d and the node c. The control circuit can activate the sensing signal S_{SEN} according to the change of the bias voltage V_{D} at the bias node d or the bandgap voltage V_{BG} at the node c. When the sensing signal S_{SEN} is activated, the bias node d is connected with the power voltage V_{SS} through the response circuit, or the node b is connected with the power voltage V_{SS} through the response circuit, or the node a is connected with the power supply voltage V_{DD} through the response circuit. When the sense signal S_{SEN} is not activated, the bias node d is disconnected from the power voltage V_{SS} through the response circuit, or the node b is disconnected from the power voltage V_{SS} through the response circuit, or the node a is disconnected from the power supply voltage V_{DD} through the response circuit.

Furthermore, the bandgap voltage generator in the bandgap reference circuit of the present invention is not restricted to the bandgap voltage generator 100 or the bandgap voltage generator 110. That is, any other appropriate bandgap voltage generator can be applied to the bandgap reference circuit of the present invention. For example, in a variant example, the bandgap voltage generator includes P-type FET transistors, but the bandgap voltage generator does not include the BJT transistors.

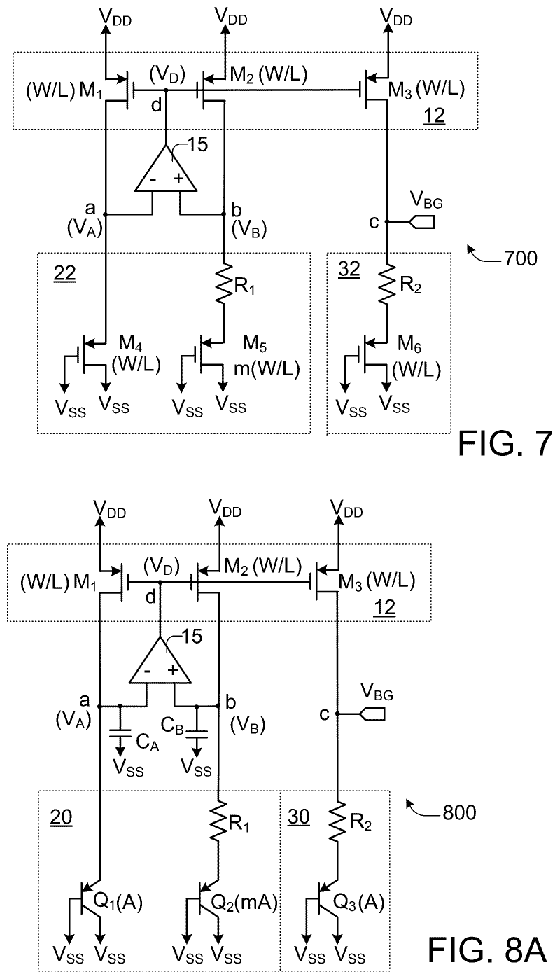

FIG. 7 is a schematic circuit diagram illustrating a variant example of the bandgap voltage generator. As shown in FIG. 7, the bandgap voltage generator 700 includes a mirroring circuit 12, an operation amplifier 15, an input circuit 22 and a load circuit 32. For succinctness, only the input circuit 22 and the load circuit 32 will be described as follows.

The input circuit 22 is connected with the node a and the node b. The input circuit 22 includes two P-type FET transistors M₄ and M₅. The aspect ratio (W/L) of the transistor M₅ is m times the aspect ratio of the transistor M₄. The gate terminal and the drain terminal of the transistor M₄ receive the power supply voltage V_{SS}. Consequently, the transistor M₄ may be regarded as a diode-connected transistor. The gate terminal and the drain terminal of the transistor M₅ receive the power supply voltage V_{SS}. Consequently, the transistor M₅ may be regarded as a diode-connected transistor. The source terminal of the transistor M₄ is connected with the node a. The first resistor R₁ is connected between the source terminal of the transistor M₅ and the node b.

The load circuit 32 is connected with the node c. The load circuit 32 includes a P-type FET transistor M₆. A second resistor R₂ is connected between the source terminal of the transistor Me and the node c. The gate terminal and the drain terminal of the transistor M₆ receive the power supply voltage V_{SS}. Consequently, the transistor M₆ may be regarded as a diode-connected transistor. The voltage at the node c is the bandgap voltage V_{BG}.

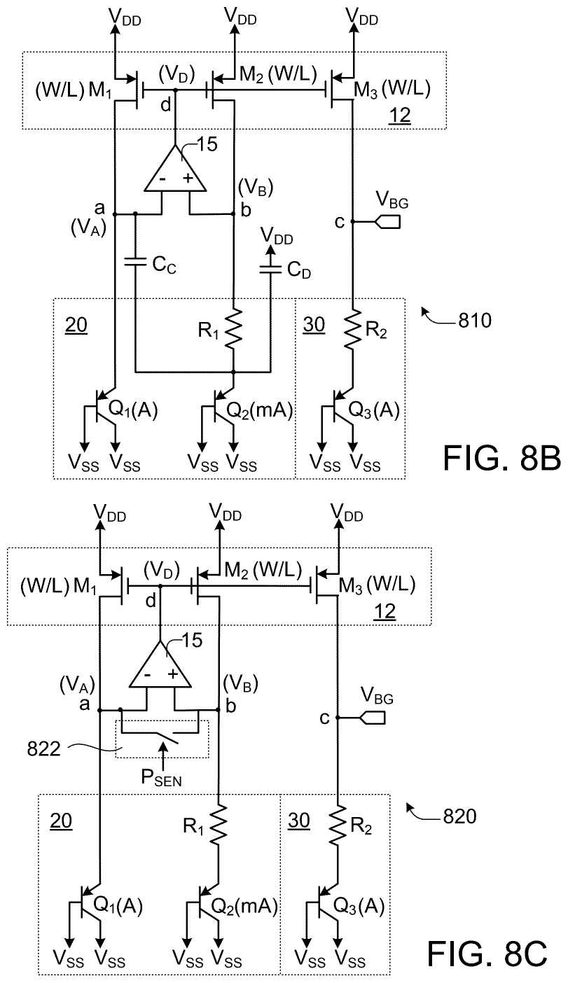

In order to prevent from the failure of the bandgap voltage generator, the bandgap reference circuit can be additionally equipped with other electronic components. FIGS. 8A, 8B and 8C are schematic circuit diagrams illustrating other three examples of the bandgap reference circuit of the present invention.

As shown in FIG. 8A, the bandgap voltage generator in the bandgap reference circuit 800 is equipped with two capacitors CA and CB. The first terminal of the capacitor CA is connected with the node a. The second terminal of the capacitor CA receives the power supply voltage V_{SS}. The first terminal of the capacitor CB is connected with the node b. The second terminal of the capacitor CB receives the power supply voltage V_{SS}.

In case that the power noise or the ground noise is large, the power noise is coupled to the nodes a and b through the capacitors CA and CB. Since the relationship between the two input terminals of the operation amplifier 15 is not affected, the voltage V_{D} from the output terminal of the operation amplifier 15 is not affected. Consequently, the problem of causing failure of the bandgap voltage generator will be solved.

In a variant example, the bandgap reference circuit 800 is equipped with a single capacitor CA. The arrangement of the single capacitor CA is sufficient to avoid the failure of the bandgap voltage generator. The capacitor CA is connected between the node a and the power supply voltage V_{SS}.

As shown in FIG. 8B, the bandgap voltage generator in the bandgap reference circuit 810 is equipped with two capacitors Cc and CD. The first terminal of the capacitor Cc is connected with the node a. The second terminal of the capacitor Cc is connected with the emitter of the transistor Q₂. The first terminal of the capacitor CD receives the power supply voltage V_{DD}. The second terminal of the capacitor CD is connected with the emitter of the transistor Q₂.

In case that the power noise or the ground noise is large, the ground noise received by the emitter of the transistor Q₂ is coupled to the node a and the power supply voltage V_{DD} through the capacitors C_{C} and C_{D}.

In a variant example, the bandgap reference circuit 810 may be equipped with a single capacitor C_{C} or a single capacitor C_{D}. Moreover, the bandgap reference circuit 810 may be additionally equipped with the capacitors CA and CB of the bandgap reference circuit 800 to couple power noise or ground noise more quickly.

As shown in FIG. 8C, the bandgap voltage generator in the bandgap reference circuit 820 is equipped with a switching circuit 822. The first terminal of the switching circuit 822 is connected with the node a. The second terminal of the switching circuit 822 is connected with the node b. The control terminal of the switching circuit 822 receives a sensing pulse P_{SEN}. The bandgap reference circuit 820 is additionally equipped with a noise detecting circuit.

In case that the power noise or the ground noise is large, the noise detecting circuit generates the sensing pulse P_{SEN} to the control terminal of the switching circuit 822. Consequently, the switching circuit 822 is temporarily in the closed state, and the node a and the node b are temporarily connected with each other. Since the relationship between the two input terminals of the operation amplifier 15 is not affected, the voltage V_{D} from the output terminal of the operation amplifier 15 is not affected. Consequently, the problem of causing failure of the bandgap voltage generator will be solved.

The circuitry structure of the noise detecting circuit for the bandgap reference circuit of FIG. 8C is not restricted. For example, the noise detecting circuit is implemented with the control circuit 212 shown in FIG. 2A. When the sensing signal S_{SEN} is activated, the noise detecting circuit generates the sensing pulse P_{SEN} to the control terminal of the switching circuit 822. Similarly, the noise detecting circuit may also be implemented with the control circuit 312 or 412.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A bandgap reference circuit, comprising:
a bandgap voltage generator comprising a mirroring circuit, an operation amplifier, an input circuit and a load circuit, wherein a negative input terminal of the operation amplifier is connected with a first node of the mirroring circuit, a positive input terminal of the operation amplifier is connected with a second node of the mirroring circuit, an output terminal of the operation amplifier is connected with a bias node of the mirroring circuit, the load circuit is connected with a third node of the mirroring circuit, the input circuit is connected with the first node and the second node of the mirroring circuit, and a voltage at the third node is a bandgap voltage; and
a detector comprising a control circuit and a response circuit,
wherein the control circuit connected with at least one of the bias node and the third node, and the control circuit activates a sensing signal according to a bias voltage at the bias node or the bandgap voltage at the third node,
wherein the response circuit receives the sensing signal, wherein when the sensing signal is activated, the first node is connected with a first power supply voltage through the response circuit, or the bias node is connected with a second power supply voltage through the response circuit, or the second node is connected with the second power supply voltage through the response circuit,
wherein when the sensing signal is not activated, the first node is disconnected from the first power supply voltage through the response circuit, or the bias node is disconnected from the second power supply voltage through the response circuit, or the second node is disconnected from the second power supply voltage through the response circuit,
wherein the first power supply voltage is greater than the second power supply voltage.

2. The bandgap reference circuit as claimed in claim 1, wherein the control circuit comprises a sensing node and a current control path, wherein a voltage at the sensing node is the sensing signal, the current control path is connected with the bias node to receive the bias voltage, and the control circuit selectively activates the sensing signal according to a change of the bias voltage.

3. The bandgap reference circuit as claimed in claim 2, wherein the control circuit comprises:
a first transistor, wherein a source terminal of the first transistor receives the first power supply voltage, a drain terminal of the first transistor is connected with the sensing node, and a gate terminal of the first transistor receives an enable signal; and
the current control path comprising a second transistor and a pull-down circuit, wherein a source terminal of the second transistor receives the first power supply voltage, a drain terminal of the second transistor is connected with the sensing node, a gate terminal of the second transistor is connected with the bias node, and the pull-down circuit is connected between the sensing node and the second power supply voltage.

4. The bandgap reference circuit as claimed in claim 3, wherein the response circuit comprises an inverter and a third transistor, wherein an input terminal of the inverter is connected to the sensing node, and a gate terminal of the third transistor is connected with an output terminal of the inverter, wherein a drain terminal and a source terminal of the third transistor are respectively connected with the bias node and the second power supply voltage, or the drain terminal and the source terminal of the third transistor are respectively connected with the second node and the second power supply voltage, or the drain terminal and the source terminal of the third transistor are respectively connected with the first power supply voltage and the first node.

5. The bandgap reference circuit as claimed in claim 3, wherein the response circuit comprises a third transistor, and a gate terminal of the third transistor is connected with the sensing node, wherein a source terminal and a drain terminal of the third transistor are respectively connected with the bias node and the second power supply voltage, or the source terminal and the drain terminal of the third transistor are respectively connected with the second node and the second power supply voltage, or the source terminal and the drain terminal of the third transistor are respectively connected to the first power supply voltage and the first node.

6. The bandgap reference circuit as claimed in claim 3, wherein the pull-down circuit comprises:
a resistor, wherein a first terminal of the resistor is connected with the sensing node; and
a third transistor, wherein a drain terminal of the third transistor is connected with a second terminal of the resistor, a source terminal of the third transistor receives the second power supply voltage, and a gate terminal of the third transistor receives the enable signal.

7. The bandgap reference circuit as claimed in claim 3, wherein the pull-down circuit comprises a third transistor, wherein a drain terminal of the third transistor is connected with the sensing node, a source terminal of the third transistor receives the second power supply voltage, and a gate terminal of the third transistor receives the enable signal.

8. The bandgap reference circuit as claimed in claim 1, wherein the control circuit comprises a sensing node and a first current control path, wherein a voltage at the sensing node is the sensing signal, the first current control path is connected with the third node to receive the bandgap voltage, and the control circuit selectively activates the sensing signal according to a change of the bandgap voltage.

9. The bandgap reference circuit as claimed in claim 8, wherein the control circuit comprises:
a first transistor, wherein a source terminal of the first transistor receives the first power supply voltage, a drain terminal of the first transistor is connected with a fourth node, and a gate terminal of the first transistor receives an enable signal;
a second transistor, wherein a drain terminal of the second transistor is connected with the sensing node, a source terminal of the second transistor receives the second power supply voltage, and a gate terminal of the second transistor receives an inverting enable signal;
a current mirror, wherein a current input terminal of the current mirror is connected with the fourth node, and a current mirroring terminal of the current mirror is connected with the sensing node;
the first current control path connected between the sensing node and the second power supply voltage; and
a second current control path connected between the fourth node and) the second power supply voltage.

10. The bandgap reference circuit as claimed in claim 9, wherein the first current control path comprises a third transistor and a fourth transistor, and the second current control path comprises a fifth transistor and a current source,
wherein a drain terminal of the third transistor is connected with the sensing node, a gate terminal of the third transistor is connected with the third node, a drain terminal of the fourth transistor is connected with a source terminal of the third transistor, a source terminal of the fourth transistor receives the second power supply voltage, and a gate terminal of the fourth transistor receives the enable signal; and
wherein a drain terminal of the fifth transistor is connected with the fourth node, a gate terminal of the fifth transistor receives the enable signal, and the current source is connected between a source terminal of the fifth transistor and the second power supply voltage.

11. The bandgap reference circuit as claimed in claim 9, wherein the response circuit comprises an inverter and a third transistor, wherein an input terminal of the inverter is connected with the sensing node, and a gate terminal of the third transistor is connected with an output terminal of the inverter, wherein a source terminal and a drain terminal of the third transistor are respectively connected with the bias node and the second power supply voltage, or the source terminal and the drain terminal of the third transistor are respectively connected with the second node and the second power supply voltage, or the source terminal and the drain terminal of the third transistor are respectively connected with the first power supply voltage and the first node.

12. The bandgap reference circuit as claimed in claim 9, wherein the response circuit comprises a third transistor, and a gate terminal of the third transistor is connected with the sensing node, wherein a drain terminal and a source terminal of the third transistor are respectively connected with the bias node and the second power supply voltage, or the drain terminal and the source terminal of the third transistor are respectively connected with the second node and the second power supply voltage, or the drain terminal and the source terminal of the third transistor are respectively connected with the first power supply voltage and the first node.

13. The bandgap reference circuit as claimed in claim 8, wherein the control circuit comprises:
a first transistor, wherein a source terminal of the first transistor receives the first power supply voltage, a drain terminal of the first transistor is connected with a fourth node, and a gate terminal of the first transistor receives an enable signal;
a second transistor, wherein a source terminal of the second transistor receives the first power supply voltage, a drain terminal of the second transistor is connected with the sensing node, and a gate terminal of the second transistor receives the enable signal;
a current mirror, wherein a current input terminal of the current mirror is connected with the fourth node, and a current mirroring terminal of the current mirror is connected with the sensing node;
the first current control path connected between the fourth node and the second power supply voltage; and
a second current control path connected between the sensing node and the second power supply voltage.

14. The bandgap reference circuit as claimed in claim 13, wherein the first current control path comprises a third transistor and a fourth transistor, and the second current control path comprises a fifth transistor and a current source,
wherein a drain terminal of the third transistor is connected with the fourth node, a gate terminal of the third transistor is connected with the third node, a drain terminal of the fourth transistor is connected with a source terminal of the third transistor, a source terminal of the fourth transistor receives the second power supply voltage, and a gate terminal of the fourth transistor receives the enable signal,
wherein a drain terminal of the fifth transistor is connected with the sensing node, a gate terminal of the fifth transistor receives the enable signal, and the current source is connected between a source terminal of the fifth transistor and the second power supply voltage.

15. The bandgap reference circuit as claimed in claim 13, wherein the response circuit comprises an inverter and a third transistor, wherein an input terminal of the inverter is connected with the sensing node, and a gate terminal of the third transistor is connected with an output terminal of the inverter, wherein a drain terminal and a source terminal of the third transistor are respectively connected with the bias node and the second power supply voltage, or the drain terminal and the source terminal of the third transistor are respectively connected with the second node and the second power supply voltage, or the drain terminal and the source terminal of the third transistor are respectively connected with the first power supply voltage and the first node.

16. The bandgap reference circuit as claimed in claim 13, wherein the response circuit comprises a third transistor, and a gate terminal of the third transistor is connected with the sensing node, wherein a source terminal and a drain terminal of the third transistor are respectively connected with the bias node and the second power supply voltage, or the source terminal and the drain terminal of the third transistor are respectively connected with the second node and the second power supply voltage, or the source terminal and the drain terminal of the third transistor are respectively connected with the first power supply voltage and the first node.

17. The bandgap reference circuit as claimed in claim 1, wherein the control circuit comprises a sensing node, a comparator and a first current control path, and a voltage at the sensing node is the sensing signal, wherein the first current control path is connected with the bias node to receive the bias voltage, a first input terminal of the comparator is connected with the first current control path, a second input terminal of the comparator is connected with the third node to receive the bandgap voltage, an output terminal of the comparator is connected with the sensing node, and the control circuit selectively activates the sensing signal according to a change of the bandgap voltage and a change of the bias voltage.

18. The bandgap reference circuit as claimed in claim 17, wherein the control circuit comprises:
the first current control path comprising a first transistor, a second transistor and a third transistor, wherein a source terminal of the first transistor receives the first power supply voltage, a gate terminal of the first transistor receives an inverted enable signal, a drain terminal of the second transistor is connected with a drain terminal of the first transistor, a gate terminal of the second transistor is connected with the bias node, a source terminal of the second transistor is connected with a fourth node, a drain terminal of the third transistor is connected with the fourth node, a gate terminal of the third transistor receives the first power supply voltage, and a source terminal of the third transistor receives the second power supply voltage; and
the comparator, wherein the first input terminal of the comparator is connected with the fourth node, the second input terminal of the comparator is connected with the third node to receive the bandgap voltage, and the output terminal of the comparator is connected with the sensing node.

19. The bandgap reference circuit as claimed in claim 17, wherein the control circuit comprises:
the first current control path comprising a first transistor, a second transistor and a third transistor, wherein a source terminal of the first transistor is connected with the bias node to receive the bias voltage, a gate terminal of the first transistor receives an inverted enable signal, a source terminal of the second transistor is connected with a drain terminal of the first transistor, a gate terminal of the second transistor is connected with a fourth node, a drain terminal of the second transistor is connected with the fourth node, a drain terminal of the third transistor is connected with the fourth node, a gate terminal of the third transistor receives the first power supply voltage, and a source terminal of the third transistor receives the second power supply voltage; and
the comparator, wherein the first input terminal of the comparator is connected with the fourth node, the second input terminal of the comparator is connected with the third node to receive the bandgap voltage, and the output terminal of the comparator is connected with the sensing node.

20. The bandgap reference circuit as claimed in claim 17, wherein the control circuit comprises:
the first current control path comprising a first transistor and a second transistor, wherein a source terminal of the first transistor receives the first power supply voltage, a gate terminal of the first transistor receives an inverted enable signal, a drain terminal of the second transistor is connected with a drain of the first transistor, a source terminal of the second transistor is connected with a fourth node, and a gate terminal of the second transistor is connected with the bias node to receive the bias voltage;
a second current control path comprising a current source, wherein the current source is connected between the first power supply voltage and a fifth node;
a current mirror, wherein a current input terminal of the current mirror is connected with the fifth node, and a current mirroring terminal of the current mirror is connected with the fourth node; and
the comparator, wherein the first input terminal of the comparator is connected with the fourth node, the second input terminal of the comparator is connected with the third node to receive the bandgap voltage, and the output terminal of the comparator is connected with the sensing node.

21. The bandgap reference circuit as claimed in claim 17, wherein the control circuit comprises:
the first current control path comprising a first transistor, a second transistor and a third transistor, wherein a source terminal of the first transistor receives the bias voltage, a gate terminal of the first transistor is connected with a fourth node, a drain terminal of the first transistor is connected with the fourth node, a drain terminal of the second transistor is connected with the fourth node, a gate terminal of the second transistor receives the first power supply voltage, a drain terminal of the third transistor is connected with a source terminal of the second transistor, a source terminal of the third transistor receives the second power supply voltage, and a gate terminal of the third transistor receives an enable signal; and
the comparator, wherein the first input terminal of the comparator is connected with the fourth node, the second input terminal of the comparator is connected with the third node to receive the bandgap voltage, and the output terminal of the comparator is connected with the sensing node.

22. The bandgap reference circuit as claimed in claim 17, wherein the response circuit comprises an inverter and a first transistor, wherein an input terminal of the inverter is connected with the sensing node, and a gate terminal of the first transistor is connected with an output terminal of the inverter, wherein a drain terminal and a source terminal of the first transistor are respectively connected with the bias node and the second power supply voltage, or the drain terminal and the source terminal of the first transistor are respectively connected with the second node and the second power supply voltage, or the drain terminal and the source terminal of the first transistor are respectively connected with the first power supply voltage and the first node.

23. The bandgap reference circuit as claimed in claim 17, wherein the response circuit comprises a first transistor, and a gate terminal of the first transistor is connected with the sensing node, wherein a source terminal and a drain terminal of the first transistor are respectively connected with the bias node and the second power supply voltage, or the source terminal and the drain terminal of the first transistor are respectively connected with the second node and the second power supply voltage, or the source terminal and the drain terminal of the first transistor are respectively connected to the first power supply voltage and the first node.

24. The bandgap reference circuit as claimed in claim 1, wherein the bandgap voltage generator comprises:
the mirroring circuit comprising a first transistor, a second transistor and a third transistor, wherein a source terminal of the first transistor receives the first power supply voltage, a drain terminal of the first transistor is connected with the first node, a gate terminal of the first transistor is connected with the bias node, a source terminal of the second transistor receives the first power supply voltage, a drain terminal of the second transistor is connected with the second node, a gate terminal of the second transistor is connected with the bias node, a source terminal of the third transistor receives the first power supply voltage, a drain terminal of the third transistor is connected with the third node, and a gate terminal of the third transistor is connected with the bias node;
a fourth transistor, wherein a source terminal of the fourth transistor receives the first power supply voltage, a drain terminal of the fourth transistor is connected with the bias node, and a gate terminal of the fourth transistor receives an enable signal;
the operation amplifier, wherein the negative input terminal of the operation amplifier is connected with the first node, the positive input terminal of the operation amplifier is connected with the second node, and the output terminal of the operation amplifier is connected with the bias node;
the input circuit comprising a fifth transistor, a sixth transistor and a first resistor, wherein an emitter of the fifth transistor is connected with the first node, a base and a collector of the fifth transistor receive the second power supply voltage, a first terminal of the first resistor is connected with the second node, an emitter of the sixth transistor is connected with a second terminal of the first resistor, and a base and a collector of the sixth transistor receive the second power supply voltage; and
the load circuit comprising a seventh transistor and a second resistor, wherein a first terminal of the second resistor is connected with the third node, an emitter of the seventh transistor is connected with a second terminal of the second resistor, and a base and a collector of the seventh transistor receive the second power supply voltage.
